(19) United States
(12) Patent Application Publication
(10) Pub. No.: US 2015/0243915 A1
(43) Pub. Date: Aug. 27, 2015

(54) ELECTRONIC DEVICE

(71) Applicant: Xerox Corporation, Norwalk, CT (US)

(72) Inventors: Anthony Wigglesworth, Oakville (CA); Yilliang Wu, Oakville (CA); Cuong Vong, Hamilton (CA)

(73) Assignee: Xerox Corporation, Norwalk, CT (US)

(21) Appl. No.: 14/189,550

(22) Filed: Feb. 25, 2014

(51) Int. Cl. H01L 51/05; H01L 51/00

(52) U.S. Cl. CPC H01L 51/052; H01L 51/0035; H01L 51/0094; H01L 51/0043; H01L 51/0003

(57) ABSTRACT

An electronic device is disclosed herein. The electronic device includes a dielectric layer and a semiconducting layer. The dielectric layer comprises a lower-k dielectric material and a higher-k dielectric material that form separate phases. The semiconducting layers includes a diketopyrrolopyrrole polymer. The combination of these two layers provides good electrical performance for the electronic device.

### BACKGROUND

The present disclosure relates to electronic devices, such as thin-film transistors (TFTs), that contain a dielectric layer and a semiconducting layer. These two layers are formed from particular components as described herein. These selections result in high performance devices with high field effect mobility. The electronic devices can be fully printed on flexible substrates as well.

TFTs are generally composed of, on a substrate, an electrically conductive gate electrode, source and drain electrodes, an electrically insulating gate dielectric layer which separate the gate electrode from the source and drain electrodes, and a semiconducting layer which is adjacent to/in contact with the gate dielectric layer and bridges the source and drain electrodes. Their performance can be determined by the field effect mobility and the current on/off ratio of the overall transistor. High mobility and high on/off ratio are desired.

Organic thin-film transistors (OTFTs) can be used in applications such as radio frequency identification (RFID) tags and backplane switching circuits for displays, such as signage, readers, and liquid crystal displays, where high switching speeds and/or high density are not essential. They also have attractive mechanical properties such as being physically compact, lightweight, and flexible.

Organic thin-film transistors can be fabricated using low-cost solution-based patterning and deposition techniques, such as spin coating, solution casting, dip coating, stencil/screen printing, flexography, gravure, offset printing, ink jet-printing, micro-contact printing, and the like. To enable the use of these solution-based processes in fabricating thin-film transistor circuits, solution processable materials are therefore required.

In this regard, gate dielectric layers may be formed by these solution-based processes. However, the gate dielectric layer so formed should be free of pinholes and possess low surface roughness (or high surface smoothness), low leakage current, a high dielectric constant, a high breakdown voltage, adhere well to the gate electrode, and offer other functionality. It should also be compatible with semiconductor materials because the interface between the dielectric layer and the organic semiconductor layer critically affects the performance of the TFT.

It would be desirable to provide electronic devices that can be formed by printing and that have high performance.

### BRIEF DESCRIPTION

The present disclosure discloses various embodiments of electronic devices that have high performance. The electronic devices comprise a dielectric layer and a semiconducting layer which are adjacent to/in contact with each other. The dielectric layer is made up of a first sublayer and a second sublayer. The first sublayer includes a higher-k dielectric material, and the second sublayer includes a lower-k dielectric material, the two sublayers being crosslinked together. The semiconducting layer comprises a diketopyrrolopyrrole (DPP) polymer.

Disclosed in various embodiments herein are an electronic device comprising a dielectric layer and a semiconducting layer; wherein the dielectric layer is formed from a first sublayer and a second sublayer, the first sublayer comprising a higher-k dielectric material and the second sublayer comprising a lower-k dielectric material, the first sublayer and the second sublayer being crosslinked together; and wherein the semiconducting layer comprises a diketopyrrolopyrrole polymer.

The higher-k dielectric material may be selected from the group consisting of a polyimide, a polyester, a polyether, a polyacrylate, a polyvinyl, a polyketone, a polysulfone, a molecular glass compound, and combinations thereof. In particular embodiments, the higher-k dielectric material comprises poly(4-vinylphenol).

The lower-k dielectric material may be an acid-sensitive dielectric material selected from the group consisting of a small molecular organosilane, an oligomeric silane, a polysiloxane, a silsesquioxane, a polyhedral oligomeric silsesquioxane, a poly(silsesquioxane), and combinations thereof. In particular embodiments, the lower-k dielectric material is poly(methyl silsesquioxane).

The weight ratio of the higher-k dielectric material to the lower-k dielectric material in the dielectric layer may be from about 4:1 to about 6:1.

The dielectric layer may have a surface roughness of less than 10 nm.

In particular embodiments, the diketopyrrolopyrrole polymer is a copolymer of Formula (A):

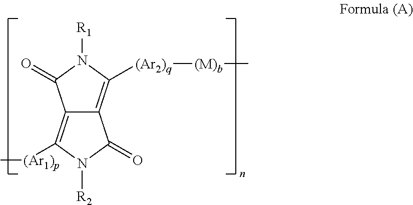

wherein R₁ and R₂ are independently hydrogen, alkyl, substituted alkyl, poly(ethylene glycol), poly(propylene glycol), aryl, substituted aryl, heteroaryl, or substituted heteroaryl; Ar₁ and Ar₂ are independently aryl, substituted aryl, heteroaryl, or substituted heteroaryl; p and q are each an integer of 0 or greater, and (p+q) is at least 2; M is a conjugated moiety; b is 0 to 5; and n is from 2 to about 5,000.

Each Ar₁ and Ar₂ unit may be independently selected from the group consisting of the following structures:

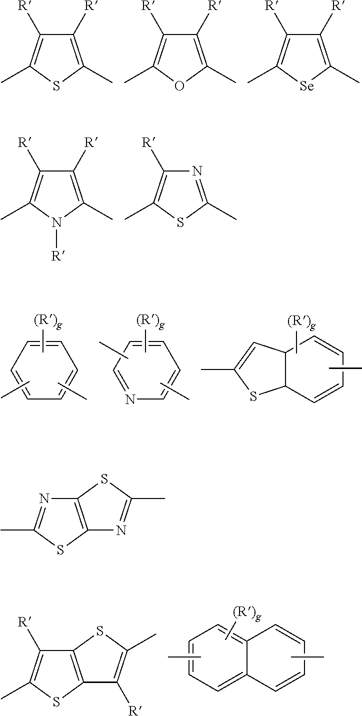

and combinations thereof, wherein each R′ is independently selected from hydrogen, alkyl, substituted alkyl, poly(ethylene glycol), poly(propylene glycol), aryl, substituted aryl, heteroaryl, substituted heteroaryl, halogen, alkoxy, alkylthio, trialkylsilyl, —CN, or —NO₂; and g is 0 to 5.

In particular embodiments, the sum of (p+q) is from 2 to 6. In others, n is from about 10 to about 30, and the polymer has a weight average molecular weight of about 20,000 to about 60,000.

In specific embodiments, the conjugated moiety M may be selected from:

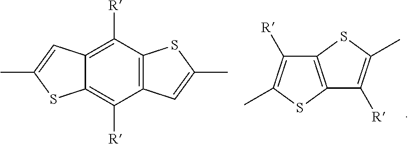

Generally, the diketopyrrolopyrrole polymer may have a weight average molecular weight from about 20,000 to about 500,000.

In particular embodiments, the higher-k dielectric material is poly(4-vinylphenol) the lower-k dielectric material is poly(methyl silsesquioxane), the first sublayer and the second sublayer are crosslinked with a poly(melamine-co-formaldehyde) resin, and the diketopyrrolopyrrole polymer has the structure of Formula (5):

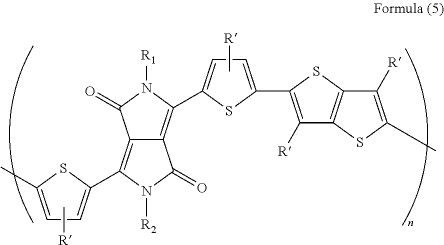

wherein each R′ is independently selected from hydrogen, alkyl, substituted alkyl, poly(ethylene glycol), poly(propylene glycol), aryl, substituted aryl, heteroaryl, substituted heteroaryl, halogen, alkoxy, alkylthio, trialkylsilyl, —CN, or —NO₂; and X is C or —Si.

Also disclosed in various embodiments are processes for fabricating an electronic device, comprising: depositing a dielectric composition on a substrate, the dielectric composition comprising a lower-k dielectric material, a higher-k dielectric material, a crosslinking agent, a thermal acid generator, a low surface tension additive, and a first solvent; curing the deposited dielectric composition to form a dielectric layer on the substrate; depositing a semiconducting composition on the substrate, the semiconducting composition comprising a diketopyrrolopyrrole polymer and a second solvent; and curing the deposited semiconducting composition to form a semiconducting layer on the substrate; wherein the lower-k dielectric material, the higher-k dielectric material, and the crosslinking agent are insoluble in the second solvent; and the diketopyrrolopyrrole polymer is insoluble in the first solvent.

The thermal acid generator may be a hydrocarbylsulfonic acid blocked or neutralized with amine. The thermal acid generator can be present in the amount of from about 0.001 to about 3 wt % of the dielectric material.

The low surface tension additive may be selected from the group consisting of a modified polysiloxane, a fluorocarbon modified polymer, a small molecular fluorocarbon compound, a polymeric fluorocarbon compound, and an acrylate copolymer. The modified polysiloxane can be a polyether modified acrylic functional polysiloxane, a polyether-polyester modified hydroxyl functional polysiloxane, or a polyacrylate modified hydroxyl functional polysiloxane. In alternative embodiments, the low surface tension additive comprises a hydroxyl functional group and a siloxane functional group.

These and other non-limiting characteristics of the disclosure are more particularly disclosed below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 represents a first embodiment of a TFT according to the present disclosure.

FIG. 2 represents a second embodiment of a TFT according to the present disclosure.

FIG. 3 represents a third embodiment of a TFT according to the present disclosure.

FIG. 4 represents a fourth embodiment of a TFT according to the present disclosure.

FIG. 5 is a diagram illustrating processes for making a DPP copolymer.

### DETAILED DESCRIPTION

A more complete understanding of the components, processes and apparatuses disclosed herein can be obtained by reference to the accompanying drawings. These figures are merely schematic representations based on convenience and the ease of demonstrating the present disclosure, and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

Numerical values should be understood to include numerical values which are the same when reduced to the same number of significant figures and numerical values which differ from the stated value by less than the experimental error of the conventional measurement technique used to determine the value.

The modifier “about” used in connection with a quantity is inclusive of the stated value and has the meaning dictated by the context (for example, it includes at least the degree of error associated with the measurement of the particular quantity). When used in the context of a range, the modifier “about” should also be considered as disclosing the range defined by the absolute values of the two endpoints. For example, the range of “from about 2 to about 10” also discloses the range “from 2 to 10.”

As used in the specification, various devices and parts may be described as “comprising” other components. The terms “comprise(s),” “include(s),” “having,” “has,” “can,” “contain(s),” and variants thereof, as used herein, are intended to be open-ended transitional phrases, terms, or words that require the presence of the named component and permit the presence of other components. However, such description should be construed as also describing the devices and parts as “consisting of” and “consisting essentially of” the enumerated components, which allows the presence of only the named component, along with any impurities that might result from the manufacture of the named component, and excludes other components.

The term “room temperature” refers to a temperature of from 20° C. to 25° C.

The term “shelf life” refers to the length of time the dielectric composition may be stored without becoming unsuitable for use. There should be no significant changes in the chemical or physical properties of the composition.

The present disclosure relates to the combination of certain dielectric layers with certain semiconducting layers in electronic devices, such as thin-film transistors (TFTs). The materials described herein can be used to make fully printed devices on a variety of substrates using simple solution processing techniques. These layers are soluble in orthogonal solvents, so that multilayer devices can be fabricated. Exemplary electronic devices include a thin-film transistor, a light-emitting diode, a sensor, a photovoltaic device, an embedded capacitor, and an electroluminescent lamp.

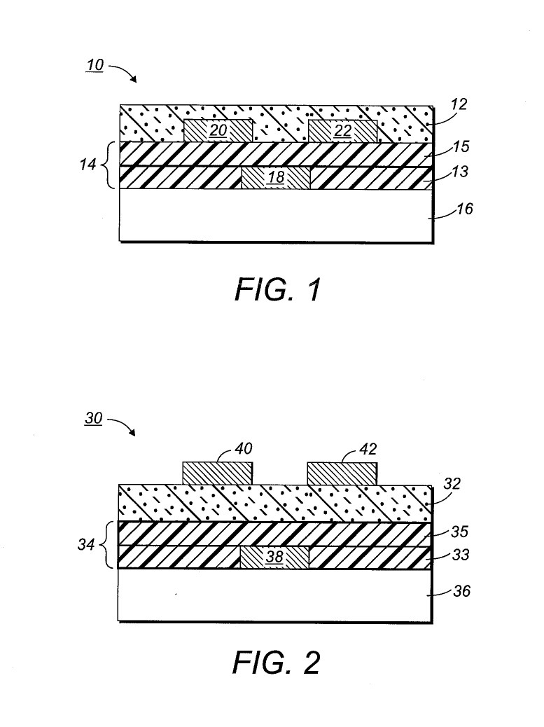

FIG. 1 illustrates a bottom-gate bottom-contact TFT. The TFT 10 comprises a substrate 16 in contact with the gate electrode 18 and a gate dielectric layer 14. The gate electrode 18 is depicted here atop the substrate 16, but the gate electrode could also be located in a depression within the substrate. The gate dielectric layer 14 separates the gate electrode 18 from the source electrode 20, drain electrode 22, and the semiconducting layer 12. The dielectric layer 14 is made up of a first sublayer 13 and a second sublayer 15. The second sublayer 15 is adjacent the semiconducting layer 12. The gate electrode 18 may contact only one of the sublayers, or may contact both of the sublayers of the dielectric layer 14. The semiconducting layer 12 runs over and between the source and drain electrodes 20 and 22. The semiconductor has a channel length between the source and drain electrodes 20 and 22.

FIG. 2 illustrates a bottom-gate top-contact TFT configuration. The TFT 30 comprises a substrate 36 in contact with the gate electrode 38 and a gate dielectric layer 34. The semiconducting layer 32 is placed on top of the gate dielectric layer 34 and separates it from the source and drain electrodes 40 and 42. The dielectric layer 34 is made up of a first sublayer 33 and a second sublayer 35. The second sublayer 35 is adjacent the semiconducting layer 32. Again, the gate electrode 38 may contact only one of the sublayers, or may contact both of the sublayers of the dielectric layer 34.

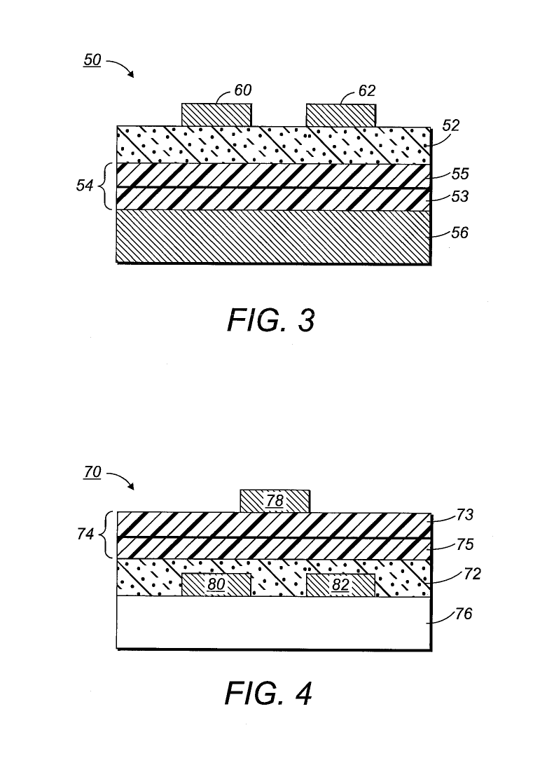

FIG. 3 illustrates another bottom-gate bottom-contact TFT configuration. The TFT 50 comprises a substrate 56 which also acts as the gate electrode and is in contact with a gate dielectric layer 54. The source electrode 60, drain electrode 62, and semiconducting layer 52 are located atop the gate dielectric layer 54. The dielectric layer 54 is made up of a first sublayer 53 and a second sublayer 55. The second sublayer 55 is adjacent the semiconducting layer 52.

FIG. 4 illustrates a top-gate top-contact TFT configuration. The TFT 70 comprises a substrate 76 in contact with the source electrode 80, drain electrode 82, and the semiconducting layer 72. The semiconducting layer 72 runs over and between the source and drain electrodes 80 and 82. The gate dielectric layer 74 is on top of the semiconducting layer 72. The gate electrode 78 is on top of the gate dielectric layer 74 and does not contact the semiconducting layer 72. The dielectric layer 74 is made up of a first sublayer 73 and a second sublayer 75. The second sublayer 75 is adjacent the semiconducting layer 72.

The components of the dielectric layer of the present disclosure will first be described, along with dielectric compositions for forming the dielectric layer. Next, the semiconducting layer of the present disclosure will be described, along with semiconducting compositions for forming the semiconducting layer. The other layers/components of the electronic devices will then be described.

The Dielectric Layer

The dielectric layer of the present disclosure is a phase-separated dielectric structure which can be made by application of one dielectric composition, or by the application of two different dielectric compositions. The dielectric layer includes a first sublayer and a second sublayer, which are crosslinked together.

In fabricating the present dielectric layer, a dielectric composition is prepared which comprises a lower-k dielectric material, a higher-k dielectric material, a crosslinking agent, and usually a first solvent or a liquid. The dielectric composition may have a shelf-life greater than about 1 month at room temperature, including a shelf-life greater than 3 months, or greater than 6 months.

Generally, one of the dielectric materials is thermally crosslinkable. The term “thermally crosslinkable” refers to the fact that the dielectric material includes functional groups that can react with an additional crosslinking agent or with other functional groups in the dielectric material itself to form a crosslinked network upon heating.

A lower-k dielectric material and a higher-k dielectric material are used to form the dielectric layer. The terms “lower-k dielectric” and “higher-k dielectric” are used to differentiate two types of material (based on the dielectric constant) in the dielectric composition and in the phase-separated dielectric layer. The lower-k dielectric material has a lower dielectric constant than the higher-k dielectric material.

In embodiments, the lower-k dielectric material is electrically insulating and is compatible or has good compatibility with the semiconducting layer in the device. The terms “compatible” and “compatibility” refer to how well the semiconductor layer performs electrically when it is adjacent to or contacting a surface rich in the lower-k dielectric material. Referring back to the figures, it is noted that the second sublayer contains the lower-k dielectric material, which is adjacent to or contacting the semiconducting layer, and is closer to the semiconducting layer than the first sublayer.

In embodiments, the lower-k dielectric material has a hydrophobic surface and therefore may exhibit satisfactory to excellent compatibility with certain semiconducting polymers. In embodiments, the lower-k dielectric material has a dielectric constant (permittivity) of for instance less than 4.0, or less than about 3.5, or particularly less than about 3.0. The lower-k dielectric material may have non-polar or weak polar groups such as a methyl group, phenylene group, ethylene group, Si—C, Si—O—Si, and the like. The lower-k dielectric material may be a silsesquioxane or a polyhedral oligomeric silsesquioxane (POSS). In particular embodiments, the lower-k dielectric material is a polymer. Representative lower-k dielectric polymers include but are not limited to homopolymers such as polystyrene, poly(4-methylstyrene), poly(chlorostyrene), poly(a-methylstyrene), polysiloxane such as poly(dimethyl siloxane) and poly(diphenyl siloxane), polysilsesquioxane such as poly(ethyl silsesquioxane), poly(methyl silsesquioxane), and poly(phenyl silsesquioxane), polyphenylene, poly(1,3-butadiene), poly(α-vinylnaphtalene), polypropylene, polyisoprene, polyisobutylene, polyethylene, poly(4-methyl-1-pentene), poly(p-xylene), poly(cyclohexyl methacrylate), poly (propylmethacrylPOSS-co-methylmethacrylate), poly(propylmethacrylPOSS-co-styrene), poly(styrylPOSS-co-styrene), poly(vinyl cinnamate), and the like. In specific embodiments, the lower-k dielectric polymer is a polysilsesquioxane, particularly poly(methyl silsesquioxane). The dielectric constant is measured at room temperature and at 1 kHz frequency.

In embodiments, the surface of the lower-k dielectric polymer, when cast as a film, has a low surface energy. To characterize the surface energy, advancing water contact angle can be used. A high contact angle indicates a low surface energy. In embodiments, the contact angle is 80 degrees or higher, or higher than about 90 degrees, or particularly higher than about 95 degrees.

In embodiments, the higher-k dielectric material is electrically insulating and contains polar groups such as a hydroxyl group, amino group, cyano group, nitro group, C═O group, and the like. In embodiments, the higher-k dielectric material has a dielectric constant of 4.0 or more, 5.0 or more, or particularly 6.0 or more. In particular embodiments, the higher-k dielectric material is a polymer. General types of higher-k dielectric polymers may include polyimide, polyester, polyether, polyacrylate, polyvinyl, polyketone, and polysulfone. Specific representative higher-k dielectric polymers include but are not limited to homopolymers such as poly(4-vinyl phenol) (PVP), poly(vinyl alcohol), and poly(2-hydroxylethyl methacrylate) (PHEMA), cyanoethylated poly(vinyl alcohol) (PVA), cyanoethylated cellulose, poly(vinylidene fluoride) (PVDF), poly(vinyl pyridine), poly(methyl methacrylate) (PMMA), copolymers thereof, and the like. In particular embodiments, the higher-k dielectric material is PVP, PVA, PHEMA, or PMMA.

In embodiments, the higher-k dielectric polymer, when cast as a film, has a high surface energy. In terms of advancing water contact angle, the angle is for instance lower than 80 degrees, or lower than about 60 degrees, or lower than about 50 degrees.

In embodiments, the difference in magnitude of the dielectric constant of the higher-k dielectric material versus the lower-k dielectric material is at least about 0.5, or at least about 1.0, or at least about 2.0, for example from about 0.5 to about 200.

In embodiments, the dielectric layer has an overall dielectric constant of more than about 4.0, or more than about 5.0, particularly more than about 6.0. The overall dielectric constant can be characterized with a metal/dielectric structure/metal capacitor. Particularly for thin-film transistor applications, a high overall dielectric constant is desirable in embodiments, so that the device can be operated at a relatively low voltage.

The dielectric material may be acid-sensitive. In particular embodiments, the lower-k dielectric material is acid-sensitive. As used herein, the term “acid-sensitive” refers to a dielectric material which is not stable when in contact with an acid at room temperature. For example, the acid may catalyze the dielectric material to react with H₂O, O₂, or itself to change the properties of the dielectric material such as molecular weight, solubility, etc. The acid-sensitive dielectric material may be a small molecular organosilane, an oligomeric silane, a polysiloxane, a silsesquioxane, a polyhedral oligomeric silsesquioxane, a poly(silsesquioxane), or combinations thereof. A small molecular organosilane has the formula Si(R)₄, where each R is independently selected from alkyl or alkoxy. An oligomeric silane has the formula R′—[—Si(R)₂-]ₘ—R″, where each R, R′, and R″ is independently selected from hydrogen, alkyl or alkoxy, and m is from 1 to 4.

In other embodiments, the acid sensitive lower-k dielectric material is a polymer comprising a silane group. Exemplary polymers include a polyacrylate, a polyvinyl, a polyimide, a polyester, a polyether, a polyketone, or a polysulfone comprising a silane group. An exemplary silane group is —Si(R)₃, where at least one R is chloro or alkoxy. Exemplary alkoxy groups include methoxy, ethoxy, cyclohexenyloxy, cyclopentenyloxy, butoxy, benzyloxy, and the like.

A crosslinking agent is present in the dielectric composition. The crosslinking agent causes crosslinking to occur between the higher-k dielectric material and the lower-k dielectric material throughout the phases. Other materials can be added into the dielectric composition. Representative crosslinking agents include poly(melamine-co-formaldehyde) resin, oxazoline functional crosslinking agents, blocked polyisocyanates, certain diamine compounds, dithiol compounds, diisocyanates, and the like.

A thermal acid generator may also be present in the dielectric composition. The thermal acid generator generates an acid when heated, catalyzing the crosslinking of the dielectric material to form a crosslinked dielectric layer that has good mechanical and electrical properties. The thermal acid generator generally should also have a good shelf-life in the dielectric composition.

In particular embodiments, the thermal acid generator is a hydrocarbylsulfonic acid. The term “hydrocarbyl” refers to a radical containing hydrogen and carbon, and which may be substituted. Exemplary hydrocarbylsulfonic acids include dodecylbenzenesulfonic acid, p-toluenesulfonic acid, and alkylnaphthalenedisulfonic acid. The thermal acid generator may be a hydrocarbylsulfonic acid blocked or neutralized with amine. Commercially available thermal acid generators include NACURE® 5225, NACURE® 2501, NACURE® 2107, and NACURE® 3483, all of which are available from King Industries.

In some embodiments, the thermal acid generator is a polymeric blocked sulfonic acid ester such as NACURE 5414; an amine-neutralized substituted naphthalenesulfonic acid such as NACURE® 3327, NACURE® 3525, NACURE® 3483, NACURE® 1419, or NACURE® 1557; an amine-neutralized substituted benzenesulfonic acid such as NACURE® 5225, NACURE® 5414, NACURE® 5528, NACURE® 2522, or NACURE® 2501; or an amine-neutralized acid phosphate such as NACURE® 4167 or NACURE® 4575.

The thermal acid generator may be present in the dielectric layer, or in the dielectric composition, in the amount of from about 0.001 to about 3 wt %, by weight of the dielectric material, including from about 0.1 to about 2 wt %.

A low surface tension additive may be present in the dielectric composition to form the dielectric layer. A low surface tension additive is an additive that is able to reduce the surface tension of the dielectric composition and/or the dielectric layer under dynamic and static conditions. This allows the dielectric composition/layer to obtain an optimal wetting and leveling effect. The low surface tension additive may be present in an amount of from about 0.0001 to about 3.0 wt % of the dielectric material, including from about 0.0001 to about 1.0 wt %. In some embodiment, the low surface tension additive does not participate in any crosslinking of the dielectric material. In other embodiments, the low surface tension additive can crosslink with the dielectric material as well, to maintain its presence in the dielectric layer. Some functional groups, such as hydroxyl or carboxylic groups, can be present in the low surface tension additive to enable the crosslinking of the low surface tension additive together with the dielectric material.

In embodiments, the low surface tension additive includes a hydroxyl, siloxane (—SiR₂O—), fluorocarbon, and/or acrylic functional group. In some embodiments, the low surface tension additive is a modified polysiloxane, a fluorocarbon modified polymer, or an acrylate copolymer. In particular embodiments, the low surface tension additive comprises a hydroxyl functional group and a siloxane functional group.

In some embodiments, the low surface tension additive is a modified polysiloxane. The modified polysiloxane may be a polyether modified acrylic functional polysiloxane, a polyether-polyester modified hydroxyl functional polysiloxane, or a polyacrylate modified hydroxyl functional polysiloxane. Exemplary low surface tension additives include SILCLEAN additives available from BYK. BYK-SILCLEAN 3700 is a hydroxyl-functional silicone modified polyacrylate in a methoxypropylacetate solvent. BYK-SILCLEAN 3710 is a polyether modified acryl functional polydimethylsiloxane. BYK-SILCLEAN 3720 is a polyether modified hydroxyl functional polydimethylsiloxane in a methoxypropanol solvent.

In other embodiments, the low surface tension additive is a fluorocarbon modified polymer, a small molecular fluorocarbon compound, a polymeric fluorocarbon compound, and the like. Exemplary fluorocarbon modified molecular or polymeric additives include a fluoroalkylcarboxylic acid, Efka®-3277, Efka®-3600, Efka®-3777, AFCONA-3037, AFCONA-3772, AFCONA-3777, AFCONA-3700, and the like.

In other embodiments, the low surface tension additive is an acrylate copolymer. Exemplary acrylate polymer or copolymer additives include Disparlon® additives from King Industries such as Disparlon® L-1984, Disparlon® LAP-10, Disparlon® LAP-20, and the like.

The low surface tension additive is different from the dielectric material used to form the dielectric layer. One way to distinguish the additive from the dielectric material is the concentration difference in the dielectric composition. As aforementioned, the additive is no more than 3.0 wt % of the dielectric material.

One, two or more suitable fluids can be used for the liquid (which facilitates the liquid depositing) or solvent which is used in the dielectric composition. In embodiments, the liquid/solvent is capable of dissolving the lower-k dielectric polymer and the higher-k dielectric polymer. Representative liquids include but are not limited to water; alcohols such as methanol, ethanol, propanol, butanol, pentanol, hexanol, ethylene glycol, dowanol, and methoxyethanol; ketones such as methyl isobutyl ketone, methyl isoamyl ketone, acetone, methyl ethyl ketone, and methyl propyl ketone; and ethers such as petroleum ether, tetrahydrofuran, and methyl t-butyl ether. The liquid/solvent may be from about 0 to about 98 wt % of the dielectric composition, including from about 50 wt % to about 90 wt %.

Inorganic nanoparticles may also be optionally included to boost the overall dielectric constant of the dielectric layer. These nanoparticles do not react with the dielectric polymers, and are generally dispersed throughout the dielectric layer. The nanoparticles have a particle size of from about 3 nm to about 500 nm, or from about 3 nm to about 100 nm. Any suitable inorganic nanoparticles can be used. Exemplary nanoparticles include metal nanoparticles such as Au, Ag, Cu, Cr, Ni, Pt and Pd; metal oxide nanoparticles such as Al₂O₃, TiO₂, ZrO₂, La₂O₃, Y₂O₃, Ta₂O₅, ZrSiO₄, SrO, SiO, SiO₂, MgO, CaO, HfSiO₄, BaTiO₃, and HfO₂; and other inorganic nanoparticles such as ZnS and Si₃N₄. The addition of inorganic nanoparticles has several advantages. First, the dielectric constant of the overall gate dielectric layer can be increased. Second, when metal nanoparticles are added, the particles can function as electron traps to lower gate leakage of the gate dielectric layer.

The concentration of each of the above listed components in the dielectric composition can vary from about 0.001 to about 99 percent by weight of the composition. The concentration of the lower-k dielectric material is for example from about 0.1 to about 30 percent by weight, or from about 1 to about 20 percent by weight. The concentration of the higher-k dielectric material is for example from about 0.1 to about 50 percent by weight, or from about 5 to about 30 percent by weight. The concentration of crosslinking agent will depend on the concentration of the dielectric polymers. The ratio of the crosslinking agent to the dielectric polymers is, for example, from about 1:99 to about 50:50, or from about 5:95 to about 30:70 by weight. The ratio of the thermal acid generator to the dielectric polymers is for example from about 1:9999 to about 5:95, or from 1:999 to about 1:99 by weight. The inorganic nanoparticles can be for example from about 0.5 to about 30 percent by weight, or from about 1 to about 10 percent by weight. In embodiments, the weight ratio of the higher-k dielectric material to the lower-k dielectric material in the dielectric composition/dielectric layer can be from about 4:1 to about 6:1.

In embodiments, the lower-k dielectric material and the higher-k dielectric material are not phase separated in the dielectric composition. The phrase “not phase separated” means that the lower-k dielectric material and the higher-k dielectric material are dissolved in the liquid. The term “dissolved” indicates total dissolution or partial dissolution of the lower-k dielectric material and the higher-k dielectric material in the liquid. The lower-k dielectric polymer, the higher-k dielectric polymer, and the liquid may be miscible to form a single phase over certain ranges of temperature, pressure, and composition. The temperature range is for example from 0 to 150° C., particularly at about room temperature. The pressure is generally about 1 atmosphere. In the dielectric composition prior to the liquid depositing, the lower-k dielectric material and the higher-k dielectric material can be present for example from about 0.1 to about 98 weight percent, or from about 0.5 to about 50 weight percent, based on the total weight of the lower-k dielectric polymer, the higher-k dielectric polymer, and the liquid. The ratio between the lower-k dielectric material to the higher-k dielectric material can be for example from about 1:99 to 99:1, or from about 5:95 to about 95:5, particularly from about 10:90 to about 40:60 (first recited value in each ratio represents the lower-k dielectric polymer).

In embodiments where the lower-k dielectric polymer, the higher-k dielectric material and the liquid are miscible to form a single phase (typically a clear solution) prior to the liquid depositing, the single phase can be confirmed by light scattering technique, or visually detected by human eyes without the assistance of any tools.

In particular embodiments, the dielectric composition used to form the dielectric layer consists of the higher-k dielectric material, the lower-k dielectric material, a crosslinking agent, a thermal acid generator, a low surface tension additive, and a solvent.

Prior to the liquid depositing, the dielectric composition may contain in embodiments aggregates of the lower-k dielectric material and/or higher-k dielectric material. These aggregates may be for example on a scale less than the wavelength of visible light, or less than 100 nm, particularly less than 50 nm. For purposes of the present disclosure, these aggregates, if present in the dielectric composition, are not considered to be phase-separated.

The dielectric composition is liquid deposited onto a substrate. Any suitable liquid depositing technique may be employed. In embodiments, the liquid depositing includes blanket coating such as spin coating, blade coating, rod coating, dip coating, and the like, and printing such as screen printing, ink jet printing, stamping, stencil printing, screen printing, gravure printing, flexography printing, and the like.

In embodiments, the liquid depositing can be accomplished in a single step. The term “single step” refers to liquid depositing both the higher-k and the lower-k dielectric materials at the same time in one dielectric composition. This is different from the process for fabricating a conventional dual-layer dielectric structure, wherein two different dielectric materials are liquid deposited separately from two different dielectric compositions. “Step” in “single step” is different from the term “pass”. In embodiments, in order to increase thickness of the dielectric structure, more than 1 pass can be carried out during the single step deposition of the dielectric composition.

In fabricating the dielectric structure, the present process involves causing phase separation of the lower-k dielectric material and the higher-k dielectric material to form a dielectric structure comprising two phases. The term “causing” includes spontaneous occurrence of phase separation during liquid deposition when the liquid evaporates. The term “causing” also includes external assistance for facilitating the phase separation during and after the liquid deposition. The dielectric composition is heated to cure the dielectric composition, resulting in the formation of a dielectric layer having a first phase and a second phase, i.e. a first sublayer and a second sublayer.

The term “phase” in “first phase” and “second phase” means a domain or domains of material in which a property such as chemical composition is relatively uniform. The term “interphase” refers to an area between the first phase and the second phase in the phase-separated dielectric structure in which a gradient in composition exists. In embodiments, the dielectric structure comprises the sequence: the first phase, optional interphase, and the second phase.

In embodiments, the “phase-separated” nature of the present phase-separated dielectric structure can be manifested by any of the following possible representative morphologies of the first phase and the second phase: (1) an interphase (in the form of a layer) present between the first phase (in the form of a layer) and the second phase (in the form of a layer); (2) one phase forms a plurality of “dots” in a continuous matrix of the other phase; (3) one phase forms a plurality of rod-shaped elements (e.g. cylinders) in a continuous matrix of the other phase; and (4) one phase is interpenetrating into the other phase to form bicontinuous domains. In embodiments, morphology (2), (3), or (4) may be present, but not (1).

The “phase-separated” nature of the present phase-separated dielectric structure regarding the morphology of the first phase and the second phase can be determined by various analyses such as for example the following: Scanning Electron Microscopy (SEM) and Atomic Force Microscopy (AFM) analysis of surface and cross-section of the dielectric structure; and Transmission Electron Microscopy (TEM) analysis of a cross-section of the dielectric structure. Other tools such as light scattering and X-ray (wide angle and small angle X-rays) scattering could also be used.

It is again noted that the first sublayer contains the higher-k dielectric material, while the second sublayer contacts the semiconducting layer and contains the lower-k dielectric material. This language should not be construed as meaning that the first sublayer contains only the higher-k dielectric material, or that the second sublayer contains only the lower-k dielectric material. Usually, the first sublayer contains a majority of the higher-k dielectric material, and a minority of the lower-k dielectric material. The second sublayer contains a majority of the lower-k dielectric material, and a minority of the higher-k dielectric material. The term “majority” means 50% or more by weight of the total weight of the lower-k dielectric material and the higher-k dielectric material in a phase of the phase-separated dielectric layer. The term “minority” means less than 50% by weight of the total weight of the lower-k dielectric material and the higher-k dielectric material in a phase of the phase-separated dielectric layer.

In more particular embodiments, the concentration of the higher-k dielectric material in the first sublayer is from about 60% to 100%, or from about 80% to 100%, and the concentration of the lower-k dielectric material in the first sublayer is from about 40% to 0%, or from about 20% to 0%. The concentration of the lower-k dielectric material in the second sublayer is from about 60% to 100%, or from about 80% to 100%, and the concentration of the higher-k dielectric material in the second sublayer is from about 40% to 0%, or from about 20% to 0%. The concentration can be controlled by various factors such as the initial ratio of the lower-k dielectric material and the higher-k dielectric material in the dielectric composition, the concentration of the dielectric polymers in the dielectric composition, the miscibility of the dielectric polymers, the processing conditions such as the annealing time and annealing temperature.

Various methods can be used to determine the concentration of the two dielectric polymers. For example, X-Ray Photoelectron Spectroscopy (XPS) can be used to analyze the concentration of each material. AFM could be used to determine domain size of different phases. TEM on a cross-section of the region could also be used to determine domain size of difference phases and concentration of each atom of different dielectric materials. In certain embodiments, the combination of different methods may be used. In case of significant variation in results from different methods, the results from TEM analysis is preferred.

To achieve phase separation, the lower-k dielectric material and higher-k dielectric material can be intentionally chosen to be immiscible or partial miscible in solid state. The miscibility (capability of a mixture to form a single phase) of the two dielectric polymers can be predicted by looking at their interaction parameter, x. Generally speaking, a material is miscible with another material which is similar to it.

In embodiments where the phase-separated dielectric layer is layered (morphology (1)), the second sublayer has a thickness for example from about 1 nm to about 500 nm, or from about 5 nm to about 200 nm, or from about 5 nm to about 50 nm. The first sublayer has a thickness for example from about 5 nm to about 2 micrometer, or from about 10 nm to about 500 nm, or from about 100 nm to about 500 nm. The resulting dielectric layer may be thinner than those normally used in electronic devices. In embodiments, the dielectric layer has a thickness of from about 10 nm to about 1000 nm. In more specific embodiments, the dielectric layer has a thickness of from about 10 nm to about 500 nm. In some embodiments, the dielectric layer has a thickness of less than 300 nm.

The resulting dielectric layer also has a low surface roughness (i.e. high surface smoothness). The surface roughness is determined by the root mean square (rms) method. Briefly, the surface roughness is measured at several points on the layer. The reported surface roughness is the square root of the arithmetic mean (average) of the squares of the measured values. In embodiments, the dielectric layer has a surface roughness of less than 10 nanometers, including less than 5 nanometers.

In embodiments, the present phase-separated dielectric structure contains intentionally created pores (also referred to as voids and apertures) such as those created using processes and materials similar to those described in for example Lopatin et al., U.S. Pat. No. 6,528,409; Foster et al., U.S. Pat. No. 6,706,464; and Carter et al., U.S. Pat. No. 5,883,219. In other embodiments, the present phase-separated dielectric structure does not contain such intentionally created pores (but pinholes may be present in certain embodiments which are not intentionally created but rather are an undesired byproduct of the present process). The pinhole density in embodiments is for example less than 50 per mm² (square millimeter), or less than 10 per mm², or less than 5 mm². In further embodiments, the present phase-separated dielectric structure is pinhole free. In embodiments, there is absent a step to create pores in the dielectric structure.

An optional interfacial layer may be present between the semiconducting layer and the phase-separated dielectric layer. The interfacial layer may be prepared using the materials and procedures disclosed in for example U.S. Pat. No. 7,282,735, the disclosure of which is totally incorporated herein by reference.

The Semiconducting Layer

The diketopyrrolopyrrole (DPP) polymer present in the semiconducting layer of the electronic devices of the present disclosure contain a diketopyrrolopyrrole monomer. In particular embodiments, the diketopyrrolopyrrole polymer is a copolymer having the structure of Formula (A):

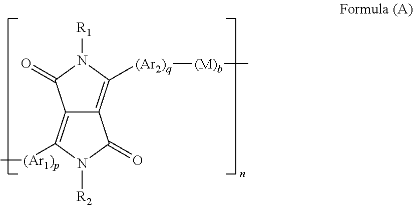

wherein R₁ and R₂ are independently hydrogen, alkyl, substituted alkyl, poly(ethylene glycol), poly(propylene glycol), aryl, substituted aryl, heteroaryl, or substituted heteroaryl; Ar₁ and Ar₂ are independently aryl, substituted aryl, heteroaryl, or substituted heteroaryl; p and q are each an integer of 0 or greater, and (p+q) is at least 2; M is a conjugated moiety; b is 0 to 5; and n is from 2 to about 5,000.

The term “alkyl” refers to a radical composed entirely of carbon atoms and hydrogen atoms which is fully saturated. The alkyl radical may be linear, branched, or cyclic. The alkyl radical can be univalent or divalent, i.e. can bond to one or two different non-hydrogen atoms.

The term “poly(ethylene glycol)” refers to a radical of the formula —(OCH₂CH₂)ₘOR, where m is an integer, and R is either hydrogen or alkyl. Exemplary poly(ethylene glycol)s include tri(ethylene glycol) monomethyl ether (m=3, R=CH₃) and tetra(ethylene glycol) monomethyl ether (m=4, R=CH₃).

The term “poly(propylene glycol)” refers to a radical of the formula —(OCH₂CH₂CH₂)ₘOR, where m is an integer, and R is either hydrogen or alkyl.

The term “aryl” refers to an aromatic radical composed entirely of carbon atoms and hydrogen atoms. When aryl is described in connection with a numerical range of carbon atoms, it should not be construed as including substituted aromatic radicals. For example, the phrase “aryl containing from 6 to 10 carbon atoms” should be construed as referring to a phenyl group (6 carbon atoms) or a naphthyl group (10 carbon atoms) only, and should not be construed as including a methylphenyl group (7 carbon atoms). The aryl radical may be univalent or divalent.

The term “heteroaryl” refers to a cyclic radical composed of carbon atoms, hydrogen atoms, and a heteroatom within a ring of the radical, the cyclic radical being aromatic. The heteroatom may be nitrogen, sulfur, or oxygen. Exemplary heteroaryl groups include thienyl, pyridinyl, and quinolinyl. When heteroaryl is described in connection with a numerical range of carbon atoms, it should not be construed as including substituted heteroaromatic radicals. Note that heteroaryl groups are not a subset of aryl groups.

The term “substituted” refers to at least one hydrogen atom on the named radical being substituted with another functional group, such as halogen, —CN, —NO₂, —COOH, and —SO₃H. An exemplary substituted alkyl group is a perhaloalkyl group, wherein one or more hydrogen atoms in an alkyl group are replaced with halogen atoms, such as fluorine, chlorine, iodine, and bromine. Besides the aforementioned functional groups, an alkyl group may also be substituted with an aryl or heteroaryl group. An aryl or heteroaryl group may also be substituted with alkyl or alkoxy. Exemplary substituted aryl groups include methylphenyl and methoxyphenyl. Exemplary substituted heteroaryl groups include 3-methylthienyl.

Generally, each alkyl group independently contains from 6 to 30 carbon atoms. Similarly, each aryl group independently contains from 4 to 24 carbon atoms. A heteroaryl group contains from 2 to 30 carbon atoms.

Some exemplary alkyl groups include methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, cyclopentyl, cyclohexyl, cycloheptyl, and isomers thereof such as 2-ethylhexyl, 2-hexyldecyl, 2-octyldodecyl, or 2-decyltetradecyl.

Some exemplary aryl and substituted aryl groups include phenyl, polyphenyl, and naphthyl; alkoxyphenyl groups, such as p-methoxyphenyl, m-methoxyphenyl, o-methoxyphenyl, ethoxyphenyl, p-tert-butoxyphenyl, and m-tert-butoxyphenyl; alkylphenyl groups such as 2-methylphenyl, 3-methylphenyl, 4-methylphenyl, ethylphenyl, 4-tert-butylphenyl, 4-butylphenyl, and dimethylphenyl; alkylnaphthyl groups such as methylnaphthyl and ethylnaphthyl; alkoxynaphthyl groups such as methoxynaphthyl and ethoxynaphthyl; dialkylnaphthyl groups such as dimethylnaphthyl and diethylnaphthyl; and dialkoxynaphthyl groups such as dimethoxynaphthyl and diethoxynaphthyl, other aryl groups listed as exemplary M groups, and combinations thereof.

Some exemplary heteroaryl groups include thiophene, thienothiophene, furan, selenophene, benzodithiophene, oxazole, isoxazole, pyridine, thiazole, isothiazole, imidazole, triazole, pyrazole, furazan, thiadiazole, oxadiazole, pyridazine, pyrimidine, pyrazine, indole, isoindole, indazole, chromene, quinoline, isoquinoline, cinnoline, quinazoline, quinoxaline, naphthylidine, phthalazine, purine, pteridine, thienofuran, imidazothiazole, benzofuran, benzothiophene, benzoxazole, benzthiazole, benzthiadiazole, benzimidazole, imidazopyridine, pyrrolopyridine, pyrrolopyrimidine, pyridopyrimidine, and combinations thereof.

Each Ar₁ and Ar₂ unit may be independently selected from the group consisting of the following structures:

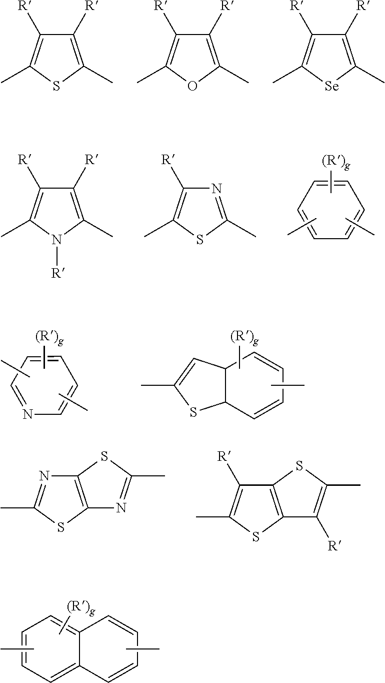

and combinations thereof, wherein each R′ is independently selected from hydrogen, alkyl, substituted alkyl, poly(ethylene glycol), poly(propylene glycol), aryl, substituted aryl, heteroaryl, substituted heteroaryl, halogen, alkoxy, alkylthio, trialkylsilyl, —CN, or —NO₂; and g is 0 to 5.

The term “alkoxy” refers to an alkyl radical which is attached to an oxygen atom, e.g. —O—CₙH₂ₙ₊₁. The oxygen atom attaches to the core of the compound.

The term “alkylthio” refers to an alkyl radical which is attached to a sulfur atom, e.g. —S—CₙH₂ₙ₊₁. The sulfur atom attaches to the core of the compound.

The term “trialkylsilyl” refers to a radical composed of a tetravalent silicon atom having three alkyl radicals attached to the silicon atom, i.e. —Si(R)₃. The three alkyl radicals may be the same or different. The silicon atom attaches to the core of the compound.

The term “halogen” refers to fluorine, chlorine, iodine, and bromine.

In particular embodiments, Ar₁ and Ar₂ are independently selected from:

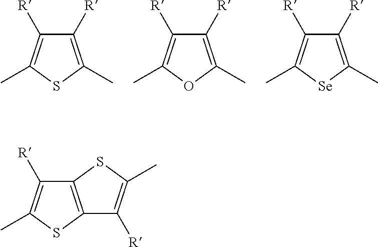

and combinations thereof, wherein each R′ is as described above.

In Formula (A), the M moiety must be different from an Ar₁ or Ar₂ unit, but can otherwise be chosen from the same moieties that Ar₁ and Ar₂ are selected from. For example, if Ar₁ and Ar₂ are unsubstituted thiophene, then M can be a substituted thiophene. In addition, the M moiety has a single ring structure. For example, biphenyl would be considered to be two M moieties, so M is phenyl and b=2. In particular embodiments, M is a conjugated moiety containing from about 4 to about 30 carbon atoms. Specific examples of the M moiety/moieties are further described for Ar″ when discussing Formula (III) below.

Initially, the diketopyrrolopyrrole (DPP) copolymer can be synthesized using a reaction mixture that contains a diketopyrrolopyrrole (DPP) monomer aryl, comonomer, palladium catalyst, organic solvent (i.e. organic phase), and an aqueous phase. The reaction mixture is then reacted to form the DPP copolymer, with the palladium catalyst being used to catalyze the reaction.

The diketopyrrolopyrrole (DPP) monomer used in the reaction mixture may have the structure of Formula (I):

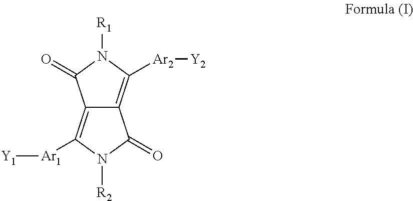

wherein Ar₁ and Ar₂ are independently aryl, substituted aryl, heteroaryl, or substituted heteroaryl; R₁ and R₂ are independently hydrogen, alkyl, substituted alkyl, poly(ethylene glycol), poly(propylene glycol), aryl, substituted aryl, heteroaryl, or substituted heteroaryl; and Y₁ and Y₂ are independently halogen.

In more specific embodiments, the diketopyrrolopyrrole (DPP) monomer may have the structure of Formula (II):

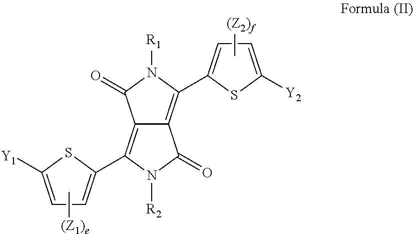

wherein R₁ and R₂ are independently hydrogen, alkyl, substituted alkyl, poly(ethylene glycol), poly(propylene glycol), aryl, or substituted aryl; Y₁ and Y₂ are independently halogen; each Z₁ and Z₂ is independently alkyl, substituted alkyl, aryl, substituted aryl, heteroaryl, substituted heteroaryl, halogen, alkoxy, alkylthio, trialkylsilyl, —CN, or —NO₂; and e and f are independently from 0 to 2.

In particular embodiments of Formula (I) and Formula (II), Y₁ and Y₂ are bromine. In some other particular embodiments of Formula (I) and Formula (II), R₁ and R₂ are hydrogen or alkyl.

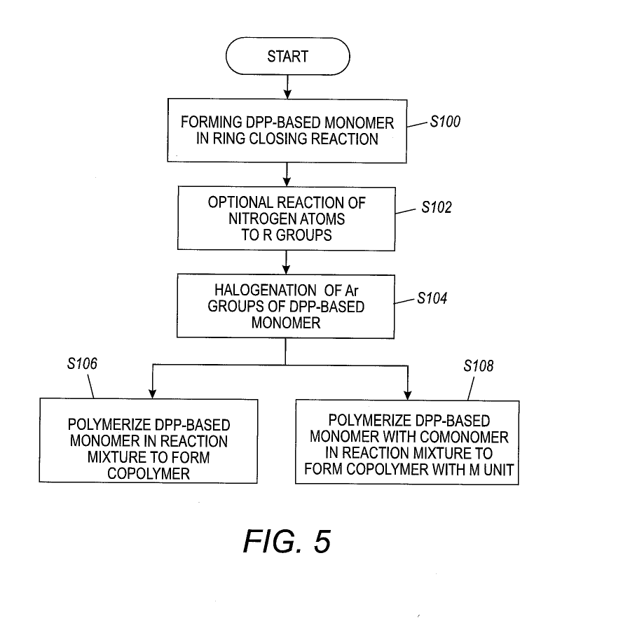

The diketopyrrolopyrrole (DPP) monomer can be prepared by a four-step process, as illustrated in FIG. 5. At step S100, a DPP (diketopyrrolopyrrole) moiety may be formed by reacting 2 moles of an appropriate nitrile or a Schiff base with one mole of a succinic acid diester in the presence of a base and an organic solvent. For example, a carbonitrile (Ar-CN) for forming the selected Ar group (e.g., thiophenecarbonitrile) is reacted with a succinate (e.g. diisopropyl succinate or di-n-butyl succinate) under suitable conditions for ring closure of the DPP moiety to form a monomer M1 of the general formula:

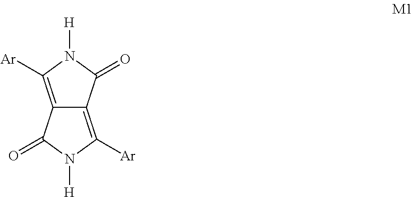

where Ar is as defined above.

For example, step S100 may be carried out in solution in the presence of a sodium alkoxide, such as t-C₅H₁₁ONa, which may be formed in situ, followed by neutralization with an organic acid, such as glacial acetic acid. The reaction may be performed at a suitable reaction temperature, such as about 85° C.

At step S102, the H groups on the nitrogen atoms of the monomer (M1) obtained at step S100 may optionally be converted from H to a selected R group by reaction of the monomer with a halide of the formula R—Y, where R is as defined above (other than H) and Y is a halogen which may be selected from chlorine, bromine, and iodine. A monomer of the following structure (M2) is thus formed:

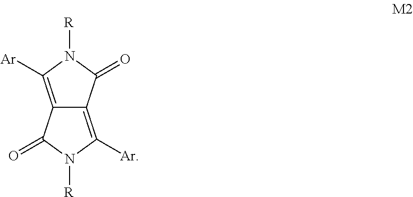

When R is aryl, substituted aryl, heteroaryl, or substituted heteroaryl, an optional palladium or copper catalyst may be required.

Step S102 may be performed in solution at a suitable reaction temperature, such as about 40 to 180° C. (e.g., about 120° C.). The reaction may be carried out in a suitable solvent, such as dimethylformamide, in the presence of an appropriate base, such as an alkali metal hydroxide or carbonate and an optional crown ether, such as 18-crown-6. Suitable bases include NaH, NaOH, KOH, t-BuONa, t-BuOK, Na₂CO₃, K₂CO₃ and the like. Usually, the molar ratio of the base to compound M1 is chosen in the range of from 0.5:1 to 50:1.

At step S104, the Ar groups are halogenated with a halogenating reagent, such as N-halosuccinimides, bromine, chlorine, or iodine, to form a monomer of the general formula:

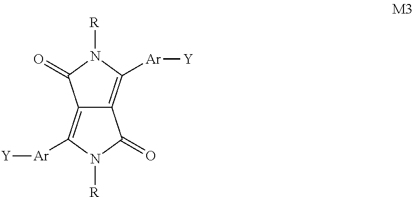

wherein Y is a halogen, such as bromine, chlorine, or iodine. Step S104 may be carried out in any suitable non-reactive medium, such as chloroform, e.g., at room temperature or above. This results in the DPP monomer of Formula (M3).

Continuing with step S106, the DKPP monomer (M3) can be polymerized to form a copolymer where no M unit is present, or in other words where b=0.

Alternatively, at step S108, the DKPP monomer (M3) is then copolymerized with a comonomer to form a copolymer, wherein the comonomer provides a moiety that is different from the Ar moiety of monomer M3. This may be one way to include a different Ar₁ or Ar₂ unit into the copolymer. This may also be a way to introduce an M unit, so that b>0. Again, the M unit should be different from the Ar₁ and Ar₂ units. The exact number of b units within each polymer strand and between M3 monomers may vary, and should be considered statistically.

Step S106 or S108 may be performed in solution in the presence of a di-tin compound, such as an hexaalkyl-di-tin or hexaaryl-di-tin compound such as hexamethylditin, hexa-n-butylditin, or hexaphenylditin, and a catalyst suitable for coupling reactions or for polycondensation reactions, optionally in the presence of copper(I) iodide. A suitable coupling catalyst is a palladium-based catalyst, e.g., a tetrakis(triarylphosphonium)-palladium catalyst, such as tetrakis(triphenylphosphine) palladium(0) (Pd(PPh₃)₄), Pd(PPh₃)₂Cl₂, PdOAc₂, Pd(dba)₃:P(o-Tol)₃, or derivatives thereof. Usually, the catalyst is added in a molar ratio of DKPP monomer to the catalyst in the range of from about 1000:1 to about 10:1, e.g., from about 100:1 to about 30:1. A suitable solvent for the reaction may be a mixture of THF and 1-methyl-2-pyrrolidinone (NMP). The reaction may be carried out under reflux at a temperature which is at or slightly above the boiling point of the solvent.

For example, the comonomer can have the formula G-M-G, where M is the conjugated moiety and G is a reactive group that depends on the polycondensation reaction. For example, in a Suzuki reaction, the reactive group G contains a boron atom. An additional base, such as K₂CO₃, Cs₂CO₃, K₃PO₄, KF, or CsF, is also required for a Suzuki reaction. Alternatively, in a Stille reaction, the reactive group G is a trialkylstannyl group such as —SnMe₃ or —Sn(n-Bu)₃.

In particular embodiments, the reaction is a Suzuki reaction that uses an aryl boronate as the comonomer. The aryl boronate used in the reaction mixture may have the structure of Formula (III):

BE-Ar″-BE Formula (III)

wherein BE represents the boronic portion, and Ar″ is a conjugated moiety. In particular embodiments, BE is selected from the group consisting of:

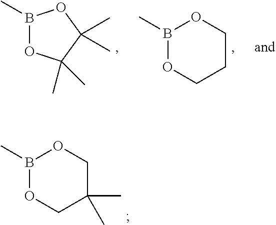

and Ar″ is selected from the group consisting of:

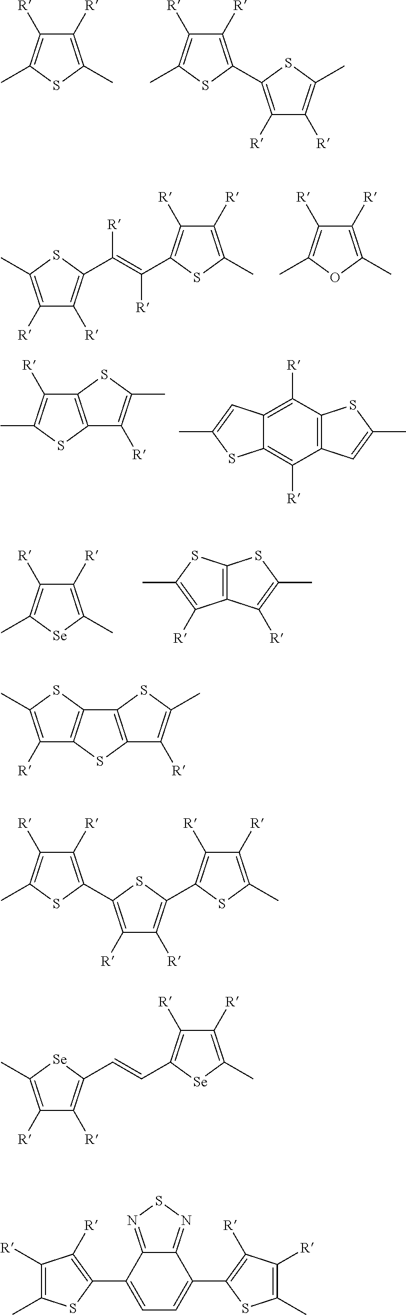

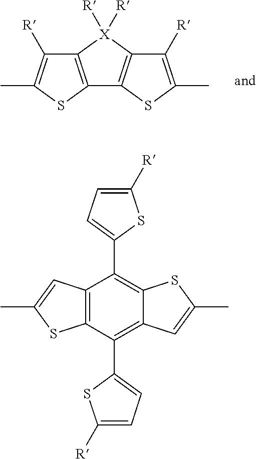

wherein each R′ is independently selected from hydrogen, alkyl, substituted alkyl, poly(ethylene glycol), poly(propylene glycol), aryl, substituted aryl, heteroaryl, substituted heteroaryl, halogen, alkoxy, alkylthio, trialkylsilyl, —CN, or —NO₂; and X is C or Si. In this regard, the cyclic boronates are preferred due to their stability under ambient conditions, ease of handling, and reactivity under the polymerization conditions.

In particular embodiments, Ar″ is selected from the group consisting of

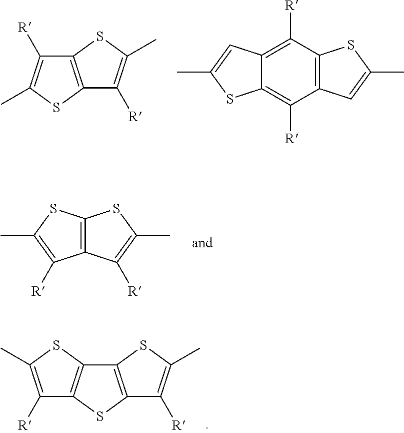

The palladium catalyst used in the reaction mixture contains a palladium metal atom. In particular embodiments, the palladium catalyst is substituted with aryl-di-tertbutyl-phosphine ligands. In particular embodiments, the palladium catalyst used in the reaction has the structure of Formula (IV):

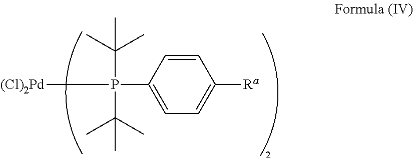

wherein R^{a} is H, —N(CH₃)₂, or —CF₃. In particular embodiments, the palladium catalyst used in the reaction is Pd-132, which has the structure shown below:

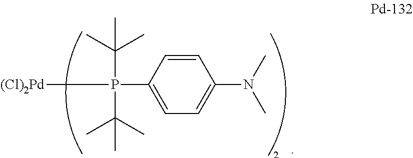

Pd-132 is especially suited for the polymerization reactions described herein.

The organic phase and the aqueous phase are used as solvents, and are immiscible with each other. The organic solvent used to form the organic phase may be selected from anisole, toluene, ethylbenzene, o-xylene, m-xylene, p-xylene, xylene, 1,2,4-trimethylbenzene, mesitylene, tetrahydronaphthalene, and mixtures thereof of such water-immiscible organic solvents. Toluene and o-xylene are preferred for the organic phase.

The aqueous phase generally includes a base selected from K₂CO₃, K₃PO₄, KHCO₃, Na₂CO₃, NaHCO₃, and mixtures thereof. The base may be added in amounts sufficient to attain a starting pH (i.e. prior to reaction) of about 8 to about 14. If desired, a water-miscible solvent, such as dimethylformamide (DMF), dimethylacetamide (DMA), n-methyl pyrrolidone (NMP), dioxolane, dioxane, or tetrahydrofuran (THF) may also be present in the aqueous phase, or used instead of water. The aqueous phase neutralizes the acid that is generated during the polymerization reaction.

The volume ratio of organic phase to aqueous phase may be from about 10:1 to about 2:1. In specific embodiments, the solvent is a mixture of o-xylene with an aqueous solution containing about 1 to about 10 molar equivalents of a base, in a volume ratio of about 3:1 (organic:aqueous). In more specific embodiments, the aqueous solution contains about 2 to about 5 molar equivalents of the base. In a specific example, the aqueous solution is 2M aqueous K₂CO₃.

If desired, the reaction mixture may also include a phase transfer catalyst. An exemplary phase transfer catalyst is known by the name “aliquat 336” or “Starks' catalyst”, and is a quaternary ammonium salt containing a mixture of octyl and decyl sidechains. The phase transfer catalyst is usually present in small amounts.

The palladium catalyst is present in an amount of from about 3 mole % to about 5 mole % of the reaction mixture. The molar ratio of the diketopyrrolopyrrole (DPP) monomer to the aryl boronate is generally about 1:1.

The reaction mixture is generally deoxygenated to prevent catalyst poisoning. The reaction mixture is then reacted to form the DPP copolymer. The reaction typically involves heating the reaction mixture for a given time period. Agitation is useful. The reaction also generally occurs under an inert atmosphere, e.g. argon or nitrogen, again to prevent catalyst poisoning. In embodiments, the reaction mixture is heated to a temperature of from 80° C. to 120° C., including about 90° C. The reaction mixture is heated for a time period of from about 2 hours to about 96 hours, including a heating time period of about 18 to about 30 hours, or about 6 hours to about 36 hours. The reaction optimizes the catalyst loading, the aqueous base in the solvent, and the reaction time. The heating of the reaction mixture can be performed by placing the reaction mixture in a heating mantle, in an oil bath, on a heating block, or in a sand bath. However, an alternative method of heating is using microwave heating, which reduces the time that the heating needs to be applied. The DPP copolymer is formed as a result of this reaction, and can subsequently be purified.

After the reacting has occurred, the diketopyrrolopyrrole (DPP) copolymer is present in the organic phase of the reaction mixture. The DPP copolymer can then be purified and isolated. The resulting diketopyrrolopyrrole copolymer has a low palladium content. In embodiments, the palladium content is less than 150 ppm, and more preferably less than 100 ppm. The resulting diketopyrrolopyrrole copolymer can also have a total metal content of less than 300 ppm, and more desirably less than 150 ppm. Such metals include palladium (Pd), boron (B), and potassium (K).

The resulting DPP copolymer can have a weight average molecular weight (Mw) from about 20,000 to about 500,000, or from about 35,000 to about 100,000, or from about 30,000 to about 60,000. The molecular weight is measured using high-temperature gel permeation chromatography in trichlorobenzene at 140° C. The resulting DPP copolymer may have a polydispersity index (PDI) of less than 4.0, including less than 3.0. In embodiments, the Mw is at least 20,000 and the PDI is less than 4.0. It should be noted that every bond formed during the polymerization here is between two heteroaromatic rings.

As mentioned before, the DPP copolymer can generally have the structure of Formula (A). In some specific embodiments of Formula (A), R₁ and R₂ are the same. In others, R₁ and R₂ are both alkyl. In additional specific embodiments of Formula (A), b is zero. In others, the sum of (p+q) is at least 2, or is at least 4. The variable a may have a value of 1 to 5. The sum of (p+q) may be at most 20. In some embodiments, the sum of (p+q) is from 2 to 6. In still other embodiments, b may be 0 or 1.

In more specific embodiments of Formula (A), the DPP copolymer has the structure of Formula (B):

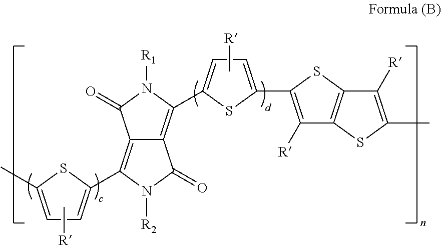

wherein R₁ and R₂ are independently hydrogen, oligo(alkylene glycol), alkyl, substituted alkyl, aryl, substituted aryl, heteroaryl, or substituted heteroaryl;
each R′ is independently hydrogen, alkyl, substituted alkyl, aryl, substituted aryl, heteroaryl, substituted heteroaryl, halogen, alkoxy, alkylthio, trialkylsilyl, —CN, or —NO₂; and c and d are independently 1 or 2.

In more specific embodiments of Formula (A), the DPP copolymer has the structure of Formula (C):

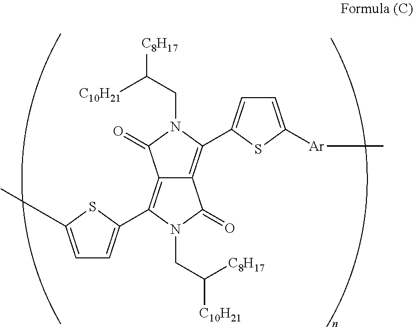

wherein Ar is aryl, substituted aryl, heteroaryl, or substituted heteroaryl having a total of 4 to 24 carbon atoms; and n is from 2 to about 5,000. In more specific embodiments, Ar can be thiophene, 2,2′-bithiophene, thienothiophene, or benzodithiophene.

Specific exemplary DPP copolymers that can be made using the processes of the present disclosure include those of Formulas (1)-(26):

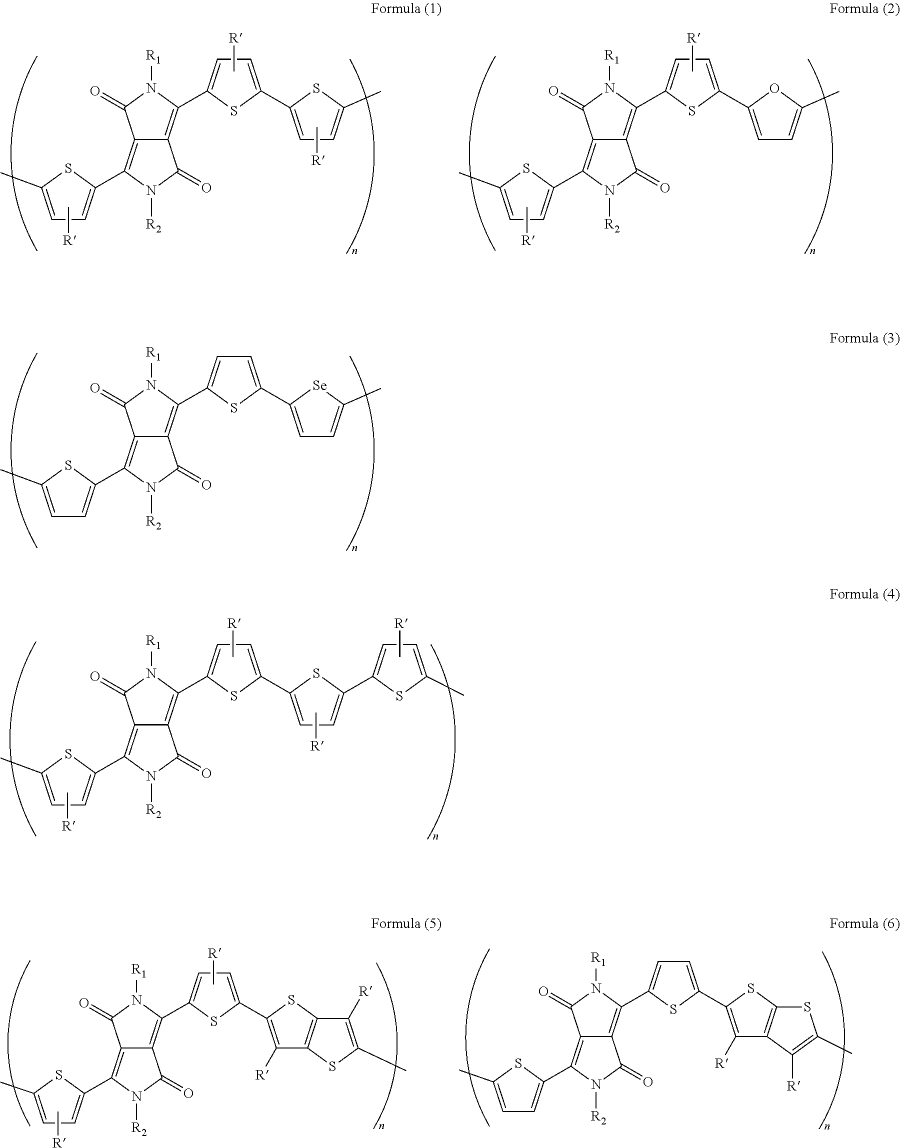

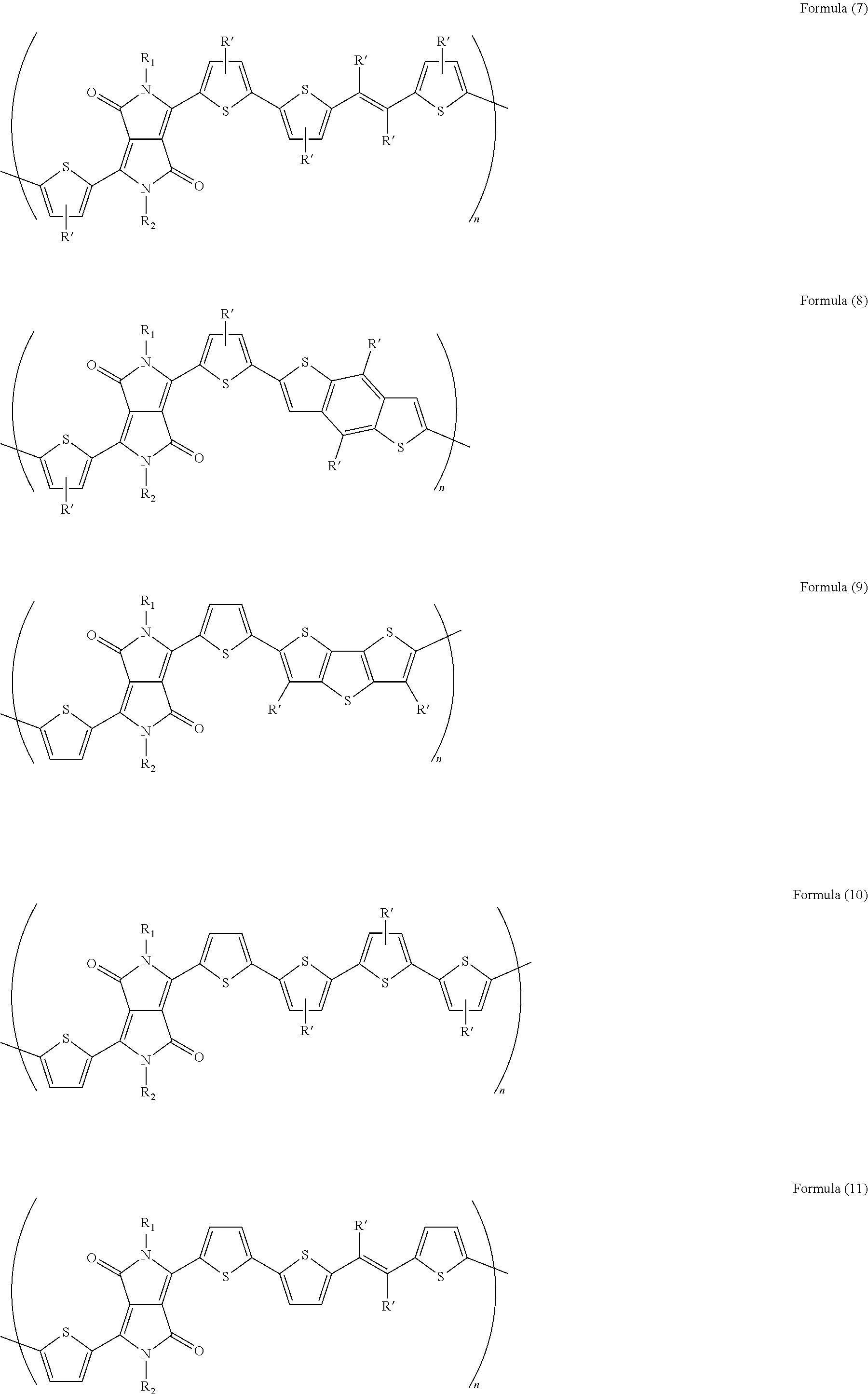

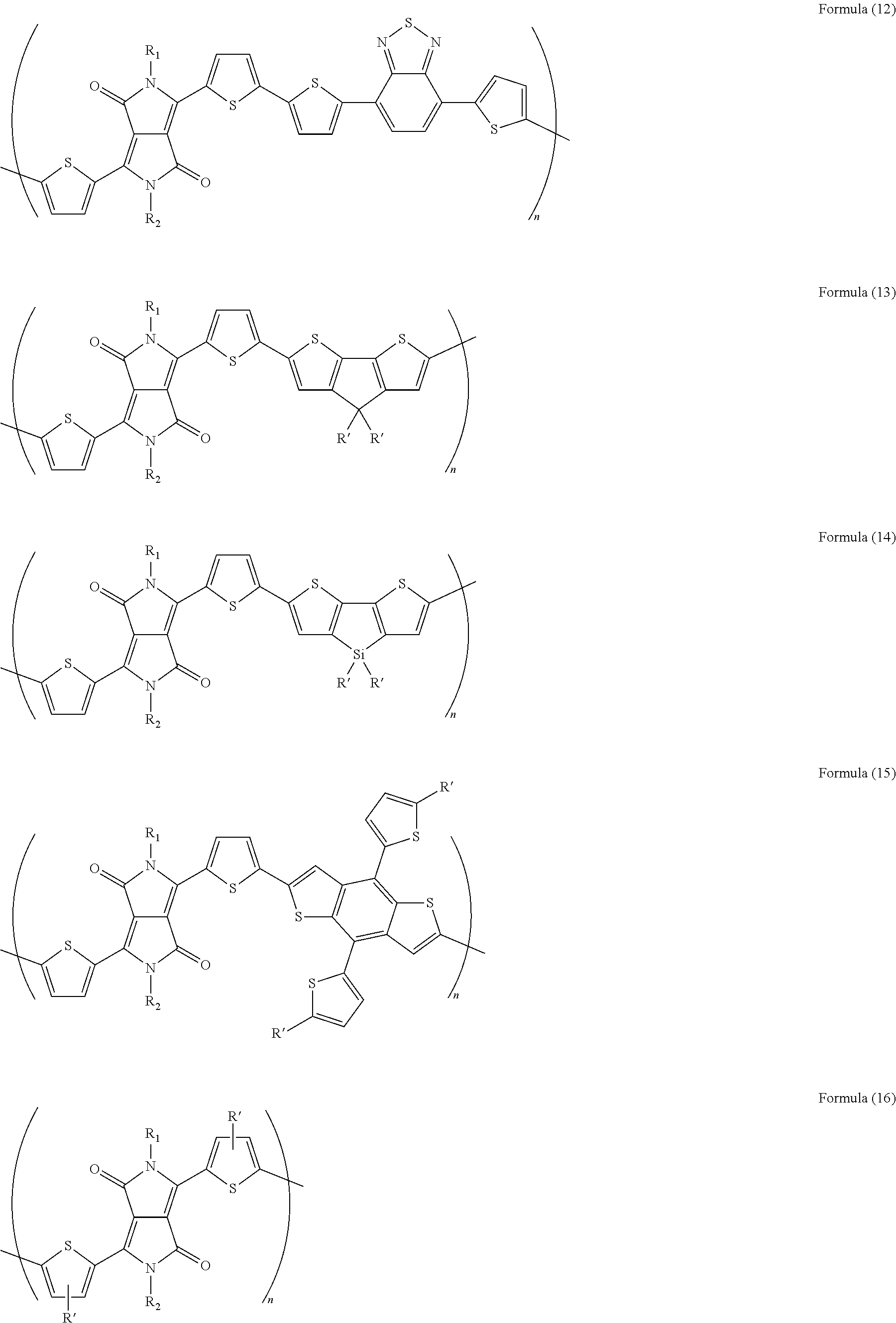

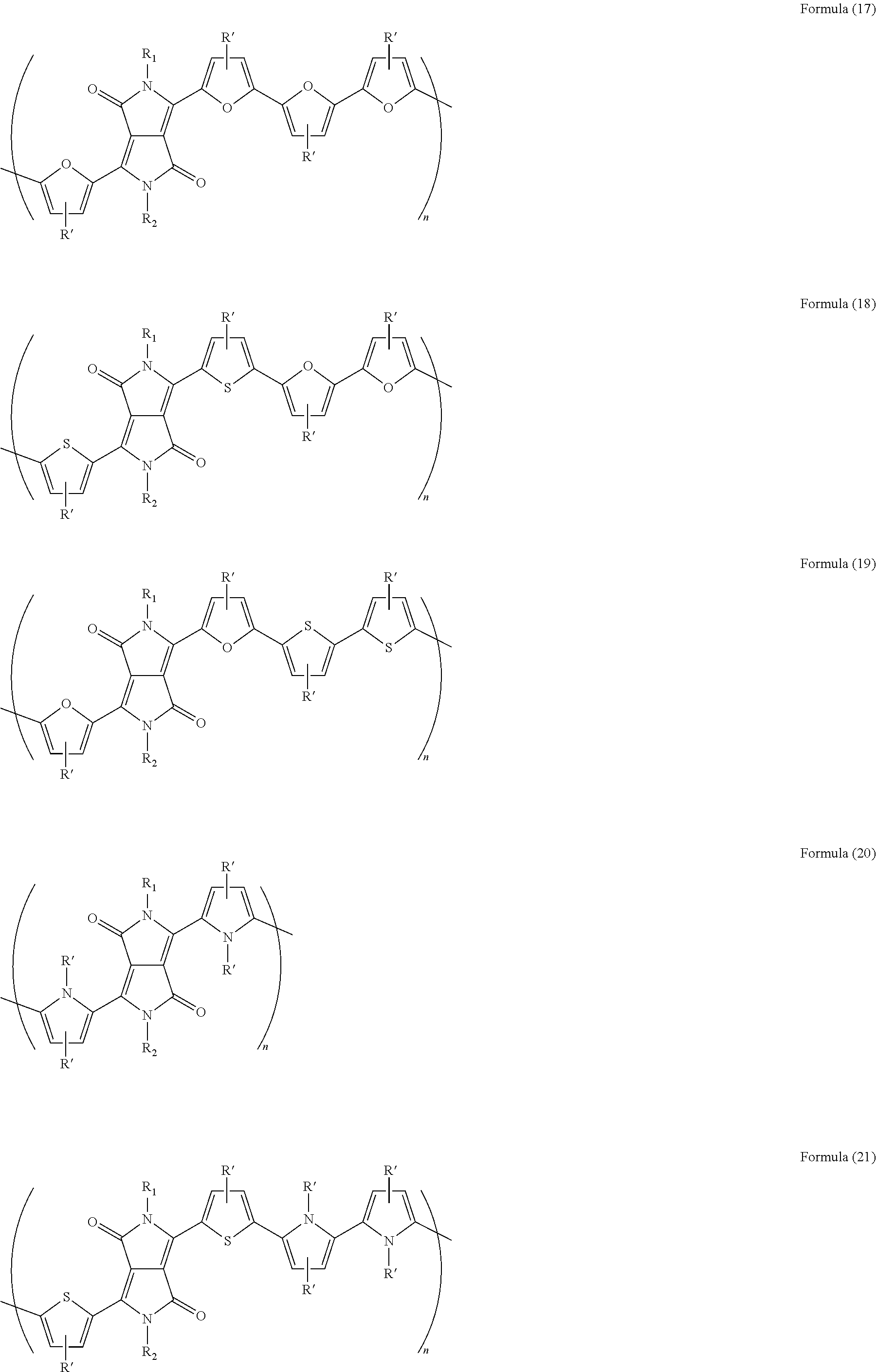

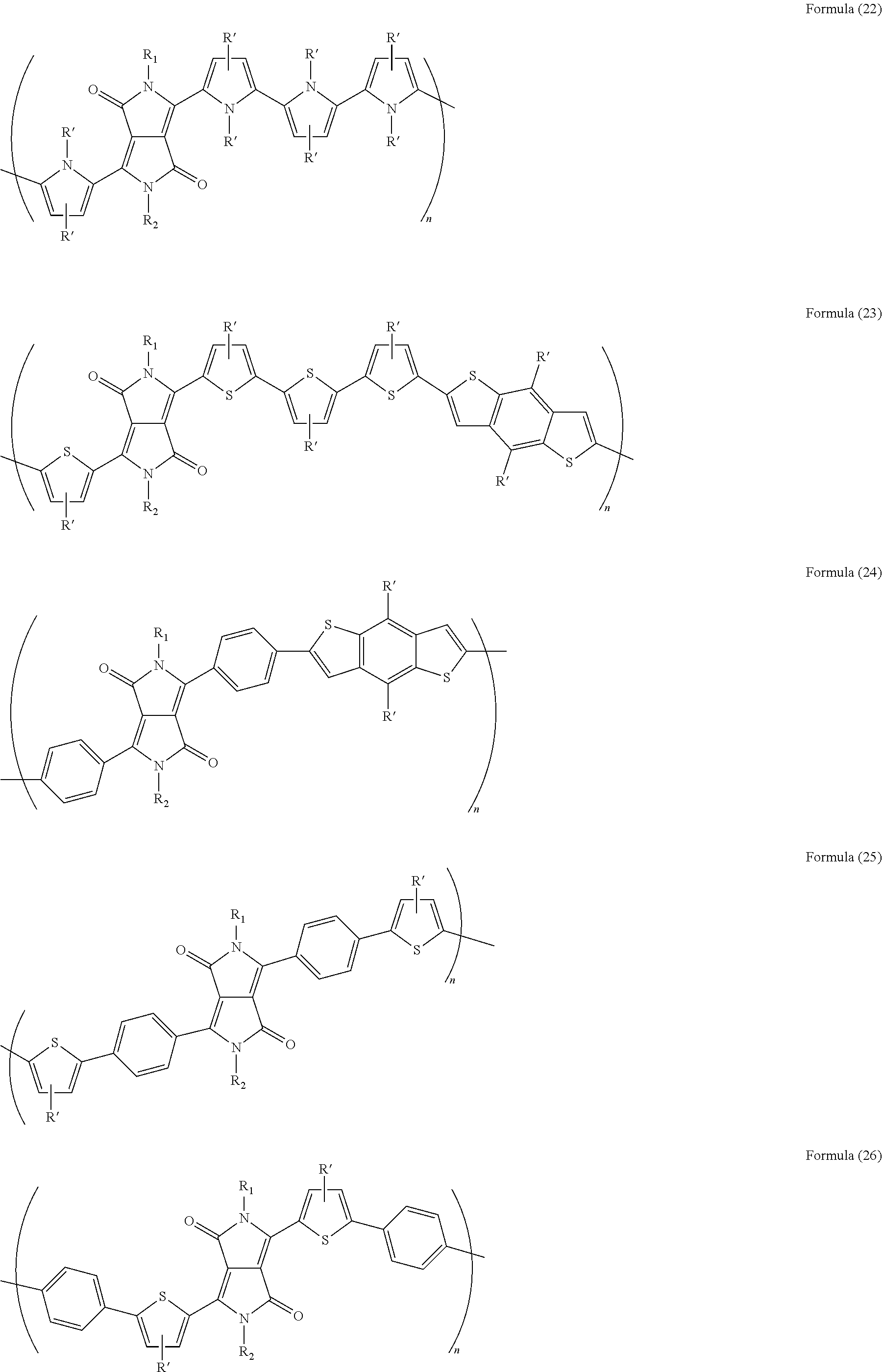

where R₁, R₂, and R′ are as defined above, and n is from 2 to about 5,000.

Semiconductor compositions comprising the DPP polymers described above are also disclosed. The semiconductor compositions may include a second solvent in which the DPP polymer is soluble. Exemplary solvents used in the semiconductor solution include hydrocarbons or aromatic hydrocarbons such as hexane, heptane, toluene, xylene, mesitylene, trimethyl benzene, ethyl benzene, tetrahydronaphthalene, decalin, methyl naphthalene, etc.; or chlorinated solvents such as chloroform, tetrachloroethane, chlorobenzene, anddichlorobenzene.

In specific embodiments, the second solvent is an aromatic non-halogenated hydrocarbon solvent selected from the group consisting of p-xylene (CAS#106-42-3), o-xylene (CAS#95-47-6), m-xylene (CAS#108-38-3), ethyl benzene (CAS#100-41-4), 1,3,5-trimethylbenzene (CAS#108-67-8), tetrahydronaphthalene (CAS#68412-24-8), and xylenes (CAS#1330-20-7). “Xylenes” refers to a mixture of the three isomers of xylene. Of course, more than one such aromatic non-halogenated hydrocarbon solvent may also be used. In other particular embodiments, the aromatic non-halogenated hydrocarbon solvent is a substituted benzene. Desirably, the aromatic non-halogenated hydrocarbon solvent is p-xylene, o-xylene, m-xylene, ethyl benzene, tetrahydronaphthalene, or xylenes.

The semiconducting layer may be formed in an electronic device using conventional processes known in the art. In embodiments, the semiconducting layer is formed using solution depositing techniques. Exemplary solution depositing techniques include spin coating, blade coating, rod coating, dip coating, screen printing, ink jet printing, stamping, stencil printing, screen printing, gravure printing, flexography printing, and the like.

The semiconducting layer formed using the semiconductor composition can be from about 5 nanometers to about 1000 nanometers deep, including from about 20 to about 100 nanometers in depth. In certain configurations, the semiconducting layer completely covers the source and drain electrodes. The semiconductor channel width may be, for example, from about 5 micrometers to about 5 millimeters with a specific channel width being about 100 micrometers to about 1 millimeter. The semiconductor channel length may be, for example, from about 1 micrometer to about 1 millimeter with a more specific channel length being from about 5 micrometers to about 100 micrometers.

The performance of a TFT can be measured by mobility. The mobility is measured in units of cm²/V·sec; higher mobility is desired. The resulting TFT using the semiconductor composition of the present disclosure may have a field effect mobility of at least 0.1 cm²/V·sec and up to 10 cm²/V·sec. The TFT of the present disclosure may have a current on/off ratio of at least 10⁴.

Different Solvents

It is noted that the dielectric layer is applied using a first solvent, and the semiconducting layer is applied using a second solvent. These two solvents should be selected so that fabrication can occur without dissolving the underlying layers. In other words, the materials in the dielectric layer (e.g. the lower-k dielectric material, the higher-k dielectric material, and the crosslinking agent) should be insoluble in the second solvent, and the diketopyrrolopyrrole (DPP) polymer should be insoluble in the first solvent. This can be achieved by selecting orthogonal solvents, in which one of the layers is soluble but the other layer is insoluble.

In embodiments, the first solvent (used for forming the dielectric layer) is water, an alcohol, a ketone, and/or an ether. The second solvent (used for forming the semiconducting layer) is an aromatic hydrocarbon. In this regard, the semiconducting DPP polymers of the present disclosure are not soluble in water, alcohols, ketones, or ethers. The crosslinking of the dielectric layer prevents mixing of the semiconducting layer with either of the sublayers of the dielectric layer.

Other Components

In addition to the dielectric layer and the semiconducting layer, a thin film transistor generally includes a substrate, an optional gate electrode, a source electrode, a drain electrode, and an optional interfacial layer.

The substrate may be composed of materials including but not limited to silicon, glass plate, plastic film or sheet. For structurally flexible devices, plastic substrate, such as for example polyester, polycarbonate, polyimide sheets and the like may be preferred. The thickness of the substrate may be from about 10 micrometers to over 10 millimeters with an exemplary thickness being from about 50 to about 100 micrometers, especially for a flexible plastic substrate and from about 0.5 to about 10 millimeters for a rigid substrate such as glass or silicon.

If desired, an interfacial layer can be placed between the dielectric layer and the semiconducting layer. The interfacial layer can be formed from organosilanes such as hexamethyldisilazane (HMDS), octyltrichlorosilane (OTS-8), octadecyltrichlorosilane (ODTS-18), and phenyltrichlorosilane (PTS).

The gate electrode is composed of an electrically conductive material. It can be a thin metal film, a conducting polymer film, a conducting film made from conducting ink or paste, or the substrate itself, for example heavily doped silicon. Examples of gate electrode materials include but are not restricted to aluminum, gold, silver, chromium, indium tin oxide, conductive polymers such as polystyrene sulfonate-doped poly(3,4-ethylenedioxythiophene) (PSS-PEDOT), and conducting ink/paste comprised of carbon black/graphite. The gate electrode can be prepared by vacuum evaporation, sputtering of metals or conductive metal oxides, conventional lithography and etching, chemical vapor deposition, spin coating, casting or printing, or other deposition processes. The thickness of the gate electrode ranges for example from about 10 to about 200 nanometers for metal films and from about 1 to about 10 micrometers for conductive polymers. Typical materials suitable for use as source and drain electrodes include those of the gate electrode materials such as aluminum, gold, silver, chromium, zinc, indium, conductive metal oxides such as zinc-gallium oxide, indium tin oxide, indium-antimony oxide, conducting polymers and conducting inks. Typical thicknesses of source and drain electrodes are, for example, from about 40 nanometers to about 1 micrometer, including more specific thicknesses of from about 100 to about 400 nanometers.

Typical materials suitable for use as source and drain electrodes include those of the gate electrode materials such as gold, silver, nickel, aluminum, platinum, conducting polymers, and conducting inks. In specific embodiments, the electrode materials provide low contact resistance to the semiconductor. Typical thicknesses are about, for example, from about 40 nanometers to about 1 micrometer with a more specific thickness being about 100 to about 400 nanometers.

The source electrode is grounded and a bias voltage of, for example, about 0 volt to about 80 volts is applied to the drain electrode to collect the charge carriers transported across the semiconductor channel when a voltage of, for example, about +10 volts to about −80 volts is applied to the gate electrode. The electrodes may be formed or deposited using conventional processes known in the art.

If desired, a barrier layer may also be deposited on top of the TFT to protect it from environmental conditions, such as light, oxygen and moisture, etc. which can degrade its electrical properties. Such barrier layers are known in the art and may simply consist of polymers.

The various components of the OTFT may be deposited upon the substrate in any order. Generally, however, the gate electrode and the semiconducting layer should both be in contact with the gate dielectric layer. In addition, the source and drain electrodes should both be in contact with the semiconducting layer. The phrase “in any order” includes sequential and simultaneous formation. For example, the source electrode and the drain electrode can be formed simultaneously or sequentially. The term “on” or “upon” the substrate refers to the various layers and components with reference to the substrate as being the bottom or support for the layers and components which are on top of it. In other words, all of the components are on the substrate, even though they do not all directly contact the substrate. For example, both the dielectric layer and the semiconducting layer are on the substrate, even though one layer is closer to the substrate than the other layer. The resulting TFT has good mobility and good current on/off ratio.

The following examples are for purposes of further illustrating the present disclosure. The examples are merely illustrative and are not intended to limit devices made in accordance with the disclosure to the materials, conditions, or process parameters set forth therein. All parts are percentages by weight unless otherwise indicated.

### Example

Top-gate bottom-contact transistors were fabricated. The dielectric film was prepared as follows:

Part A. In a brown glass bottle poly(vinyl phenol) (Mw=25 K Da) (1 gram) was dissolved in n-butanol (13.5 grams) by immersing in an ultrasonic bath for 15 minutes. To the solution was added melamine-co-formaldehyde resin (84-wt. % in butanol) (1 gram), NACURE 5225 (0.07 grams) and SILCLEAN 3700 (0.02 grams). The formulation was mixed thoroughly and stored at room temperature.

Part B. A poly(methyl silsesquioxane) solution was prepared by treating a solution of methyl(trimethoxy)silane (4.08 grams) in methyl-isobutylketone (9.24 grams) with a solution of 0.1 wt-% aqueous HCl (0.88 grams) in tetrahydrofuran (5.13 grams) at 0° C. under an Argon atmosphere. After complete addition of the HCl solution, the reaction was heated to 60° C. After 18 hours, the solution was cooled to room temperature and the formulation was transferred to a polypropylene bottle and stored at room temperature.

In a 5 dram vial, Part A (1 gram) was mixed with Part B (0.1 gram) in a 10:1 ratio. The dielectric formulation was mixed thoroughly using a vortex mixer and filtered through a 0.45 micron syringe filter. The formulation was spin-coated onto a plasma cleaned silicon wafer with 2 nm native SiO₂ layer at 2000 rpm for 120 seconds. The substrate was removed and cured in an oven at 160° C. for 30 minutes. The film was ˜500 nm thick and showed excellent solvent resistance to toluene, methanol and dichloromethane.

The semiconducting layer was prepared as follows:

A 0.7 wt % solution of polymer (5-a) (Mw=48.5 K) in p-xylene was prepared by dissolving the polymer (7 mg) in p-xylene (1 gram) at 100° C. on a hot plate. After 10-15 minutes of heating, the deep blue solution was removed from the hot plate and cooled to room temperature. The polymer solution was filtered through a 0.45 micron syringe filter and spin-coated onto the dielectric film at 1000 rpm for 60 seconds. The semiconductor film was dried in a vacuum oven at 80° C. for 10 minutes and subsequently annealed at 140° C. for 10 minutes. The heating was turned off and the oven was cooled to room temperature under vacuum. The device fabrication was completed by thermally evaporating gold source-drain electrodes.

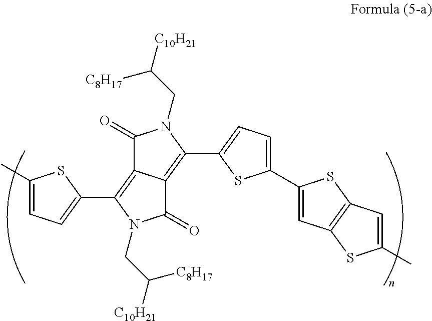

Three devices were made on each of two different substrates. Device performance was evaluated using a Keithley SCS-4200 system and results are shown in Table 1.

TABLE 1
Average device performance

| Substrate | μ_{avg} (cm/V · sec) | On/Off |
|---|---|---|
| Silicon | 0.20 | 4.6 × 10⁴ |
| Polyethylene terephthalate | 0.15 | 2.2 × 10⁴ |
| (PET) | | |

The present disclosure has been described with reference to exemplary embodiments. Obviously, modifications and alterations will occur to others upon reading and understanding the preceding detailed description. It is intended that the present disclosure be construed as including all such modifications and alterations insofar as they come within the scope of the appended claims or the equivalents thereof.

1. An electronic device comprising a dielectric layer and a semiconducting layer;
wherein the dielectric layer is formed from a first sublayer and a second sublayer, the first sublayer comprising a higher-k dielectric material and the second sublayer comprising a lower-k dielectric material, the first sublayer and the second sublayer being crosslinked together; and
wherein the semiconducting layer comprises a diketopyrrolopyrrole polymer.

2. The electronic device of claim 1, wherein the higher-k dielectric material is selected from the group consisting of a polyimide, a polyester, a polyether, a polyacrylate, a polyvinyl, a polyketone, a polysulfone, a molecular glass compound, and combinations thereof.

3. The electronic device of claim 1, wherein the higher-k dielectric material comprises poly(4-vinylphenol).

4. The electronic device of claim 1, wherein the lower-k dielectric material is an acid-sensitive dielectric material selected from the group consisting of a small molecular organosilane, an oligomeric silane, a polysiloxane, a silsesquioxane, a polyhedral oligomeric silsesquioxane, a poly(silsesquioxane), and combinations thereof.

5. The electronic device of claim 1, wherein the lower-k dielectric material is poly(methyl silsesquioxane).

6. The electronic device of claim 1, wherein the weight ratio of the higher-k dielectric material to the lower-k dielectric material in the dielectric layer is from about 4:1 to about 6:1.

7. The electronic device of claim 1, wherein the dielectric layer has a surface roughness of less than 10 nm.

8. The electronic device of claim 1, wherein the diketopyrrolopyrrole polymer is a copolymer of Formula (A): 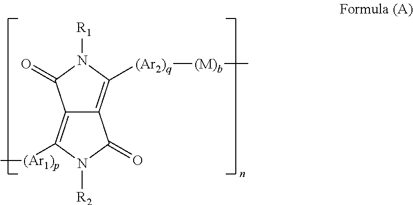
wherein R₁ and R₂ are independently hydrogen, alkyl, substituted alkyl, poly(ethylene glycol), poly(propylene glycol), aryl, substituted aryl, heteroaryl, or substituted heteroaryl; Ar₁ and Ar₂ are independently aryl, substituted aryl, heteroaryl, or substituted heteroaryl; p and q are each an integer of 0 or greater, and (p+q) is at least 2; M is a conjugated moiety; b is 0 to 5; and n is from 2 to about 5,000.

9. The electronic device of claim 8, wherein each Ar₁ and Ar₂ unit is independently selected from the group consisting of the following structures: 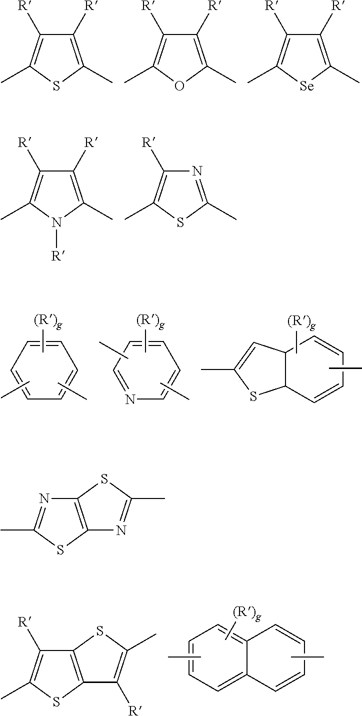
and combinations thereof, wherein each R′ is independently selected from hydrogen, alkyl, substituted alkyl, poly(ethylene glycol), polypropylene glycol), aryl, substituted aryl, heteroaryl, substituted heteroaryl, halogen, alkoxy, alkylthio, trialkylsilyl, —ON, or —NO₂; and g is 0 to 5.

10. The electronic device of claim 8, wherein the sum of (p+q) is from 2 to 6.

11. The electronic device of claim 8, wherein n is from about 10 to about 30, and the polymer has a weight average molecular weight of about 20,000 to about 60,000.

12. The electronic device of claim 8, wherein the conjugated moiety M is selected from:

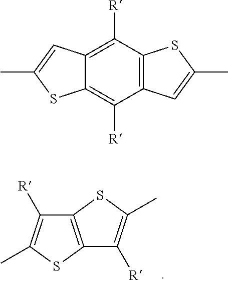

13. The electronic device of claim 1, wherein the diketopyrrolopyrrole polymer has a weight average molecular weight from about 20,000 to about 500,000.

14. The electronic device of claim 1, wherein the higher-k dielectric material is poly(4-vinylphenol) the lower-k dielectric material is poly(methyl silsesquioxane), the first sublayer and the second sublayer are crosslinked with a poly(melamine-co-formaldehyde) resin, and the diketopyrrolopyrrole polymer has the structure of Formula (5) 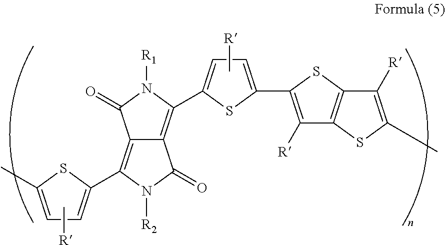
wherein each R′ is independently selected from hydrogen, alkyl, substituted alkyl, poly(ethylene glycol), poly(propylene glycol), aryl, substituted aryl, heteroaryl, substituted heteroaryl, halogen, alkoxy, alkylthio, trialkylsilyl, —CN, or —NO₂; and X is C or Si.

15. A process for fabricating an electronic device, comprising:
depositing a dielectric composition on a substrate, the dielectric composition comprising a lower-k dielectric material, a higher-k dielectric material, a crosslinking agent, a thermal acid generator, a low surface tension additive, and a first solvent;
curing the deposited dielectric composition to form a dielectric layer on the substrate;
depositing a semiconducting composition on the substrate, the semiconducting composition comprising a diketopyrrolopyrrole polymer and a second solvent; and
curing the deposited semiconducting composition to form a semiconducting layer on the substrate;
wherein the lower-k dielectric material, the higher-k dielectric material, and the crosslinking agent are insoluble in the second solvent; and the diketopyrrolopyrrole polymer is insoluble in the first solvent.

16. The process of claim 15, wherein the thermal acid generator is a hydrocarbylsulfonic acid blocked or neutralized with amine.

17. The process of claim 15, wherein the thermal acid generator is present in the amount of from about 0.001 to about 3 wt % of the dielectric material.

18. The process of claim 15, wherein the low surface tension additive is selected from the group consisting of a modified polysiloxane, a fluorocarbon modified polymer, a small molecular fluorocarbon compound, a polymeric fluorocarbon compound, and an acrylate copolymer.

19. The process of claim 18, wherein the modified polysiloxane is a polyether modified acrylic functional polysiloxane, a polyether-polyester modified hydroxyl functional polysiloxane, or a polyacrylate modified hydroxyl functional polysiloxane.

20. The process of claim 15, wherein the low surface tension additive comprises a hydroxyl functional group and a siloxane functional group.
